(19) United States
(12) Patent Application Publication
(10) Pub. No.: US 2011/0142186 A1
(43) Pub. Date: Jun. 16, 2011

(54) METHOD AND DEVICE FOR DETECTING DEPOSITS COMPRISING AT LEAST ONE FERROMAGNETIC MATERIAL ON OR NEAR THE EXTERNAL WALL OF A TUBE

(76) Inventor: Antoine Gemma, Marseille (FR)

(21) Appl. No.: 12/992,882

(22) PCT Filed: Mar. 15, 2009
(86) PCT No.: PCT/EP09/55949

§ 371 Date: Feb. 28, 2011

(30) Foreign Application Priority Data
May 16, 2008 (FR) 0853200

(51) Int. Cl. G21C 17/017; G01R 33/16

(52) U.S. Cl. 376/249; 324/201

(57) ABSTRACT

The present invention relates to a method of detecting deposits comprising at least one ferromagnetic material, such as nickel, magnetite or the like, on or near the external wall of a tube, notable in that it comprises at least the following steps of: moving a magnetized source inside the tube in the lengthwise direction using an electric motor, measuring the strength of the current in the electric motor, and determining the position and/or the thickness and/or the volume of the said deposit as a function of the variations in the strength of the current measured in the electric motor. Another subject of the invention is a device implementing the said method.

### FIELD OF THE INVENTION

The present invention relates to the general field of processes and devices for magnetic detection and more particularly the field of processes and devices for detection fouling or clogging by deposits of ferromagnetic materials on or near cooling tubes of a steam generator of a pressurised nuclear water reactor known as PWR.

### BACKGROUND OF THE INVENTION

In the field of electronuclear plants of PWR type according to the acronym “Pressurised Water Reactor”, it is well known that heat produced in the core of the reactor is transmitted by means of a closed circuit known as the primary circuit in which water circulates to a so-called secondary circuit whereof the water transformed into steam powers turbines to produce electricity.

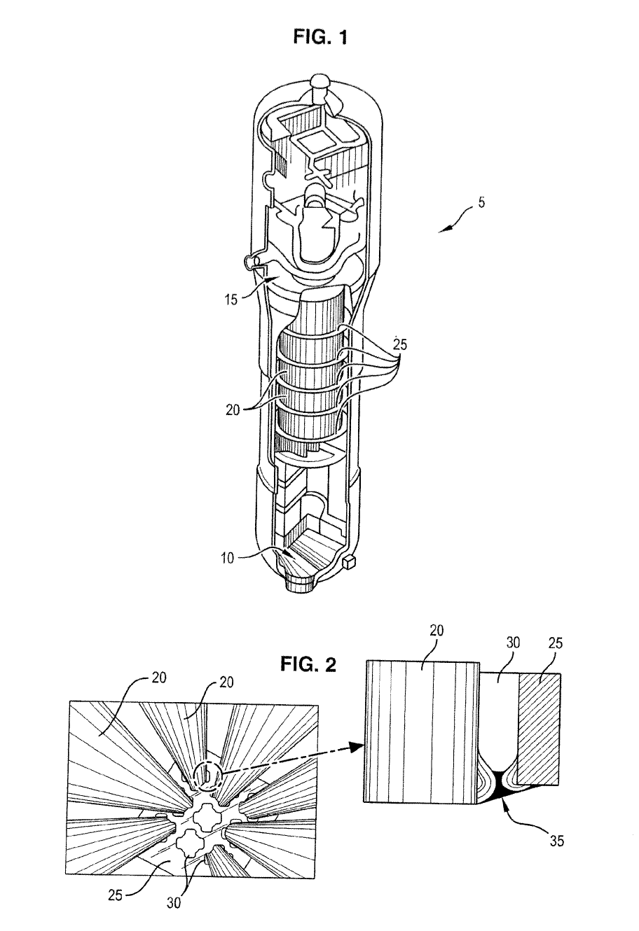

In reference to FIG. 1 which illustrates a steam generator in exploded perspective, each electronuclear plant of PR type generally comprising three or four steam generators, said steam generator is constituted by a confinement enclosure 5 receiving the primary circuit 10 and the secondary circuit 15. The thermal exchange between the primary circuit 10 and the secondary circuit 15 occurs via plurality of tubes 20 in an inverted U. Said tubes 20 are held in place by spacer plates 25 immobilised by ties fixed in the lower part of the steam generator.

In reference to FIG. 2 which illustrates a perspective view of a detail of the spacer plates 25 and the tubes 20, said spacer plates 25 comprise holes in the form of so-called quadrifoliage hollows through which said cylindrical tubes 20 pass.

It is known that clogging deposits 35 form at the level of the quadrifoliages 25 (FIG. 2) between the tubes 20 and the spacer plates 25. The consequence of these deposits 35 on the one hand, as a function of normal behaviour, is to modify the mechanical stresses on the tubes 4 and on the other hand, in case of incident or accident, to boost forces on the spacer plates 25 thus increasing the risk of rupturing the tubes 20.

Also, it is likewise known that so-called fouling deposits form on the external surface of tubes 20 causing a drop in performance of thermal exchange in the steam generator.

To eliminate these clogging or fouling deposits, it is known to clean the tubes and spacer plates by chemical cleaning processes. These processes consist of injecting chemical reagents into the secondary circuit of steam generators to demolish and dissolve these oxide deposits such as magnetites.

However, the quantity of reagents to be injected depends on the quantity of oxides present in the steam generators.

Consequently, the quantity of oxides needs to be determined in advance.

For this purpose, processes and devices are well known which detect deposits of magnetites using an axial probe with low-frequency Foucault current, said probe being introduced into the tubes of the steam generator, whereof the measurements are correlated with televisual images or online standards representative of deposits encountered.

The drawback to this type of process is that it needs analysis time of around 1 month for acquisition of data, considerably driving up costs. Also, measurements obtained by this type of process exhibit low precision.

The process and device for detecting deposits described in US patent U.S. Pat. No. 4,088,946 are also known. Said device comprises a probe with Foucault current which is moved at a constant speed in a tube to detect deposits.

In the same way as earlier, this probe exhibits low precision and needs acquisition of video images.

Other processes and devices for detection of deposit on the external wall of tubes having the same drawbacks are described especially in French patent application FR 2 459 490 and in US patent U.S. Pat. No. 4,700,134.

### BRIEF DESCRIPTION OF THE INVENTION

One of the aims of the invention is therefore to rectify these drawbacks by proposing a process and a detection device for deposits comprising at least one ferromagnetic material on or near the external wall of a tube, more particularly designed for detection of deposit on or near tubes of a steam generator of a electronuclear plant of PWR type, which is simple in design and minimally costly and has high precision and is substantially reliable.

For this purpose and in keeping with the invention, a process for detecting deposits is proposed, comprising at least one ferromagnetic material, such as nickel, magnetite or similar, on or near the external wall of a tube, significant in that it comprises at least the following steps of moving a magnetised source inside the tube in the direction of its length by means of an electric motor, measuring the intensity of the current in the electric motor, and determining the position and/or thickness and/or volume of said deposit as a function of the variations in intensity of the current measured in the electric motor.

The magnetised source preferably consists of at least one permanent magnet.

Also, said magnetised source is moved in the tube at a constant speed, said magnetised source being moved in a first direction and then in its opposite direction.

Also, the step for determining the position and/or thickness and/or volume of said deposit comprises a comparison step of the variation in intensity of the current measured in the motor with a reference model and/or a calibrated model.

Another object of the invention relates to a detection device executing the process significant in that it comprises at least one magnetised source, moving means of said magnetised source inside of said tube in the direction of the length comprising an electric motor, means for measuring the intensity of the current in said electric motor and means for determining the position and/or thickness and/or volume of said deposit as a function of variations in intensity of the current measured in the electric motor.

Said magnetised source preferably consists of at least one permanent magnet.

Said moving means of the magnetised source consist of a piston whereof one of the ends bears said magnetised source and whereof the opposite end comprises a bolt cooperating with an endless screw solid with the rotary drive axle.

Also, the rotary drive axle consists of the output axle of a reducer coupled to an electric motor.

By way of advantage, the device comprises blocking means of drive means inside a tube.

### BRIEF DESCRIPTION OF THE DIAGRAMS

Other advantages and characteristics will emerge from the following description of several variant embodiments, given by way of non-limiting examples, of the device for detecting magnetic deposits on or near an amagnetic tube according to the invention, from the attached diagrams, in which:

FIG. 1 is an exploded perspective view of a steam generator of electronuclear plants of PWR type,

FIG. 2 is a perspective view of a detail of the tubes passing in the quadrifoliages of spacer plates, said quadrifoliages comprising clogging deposits,

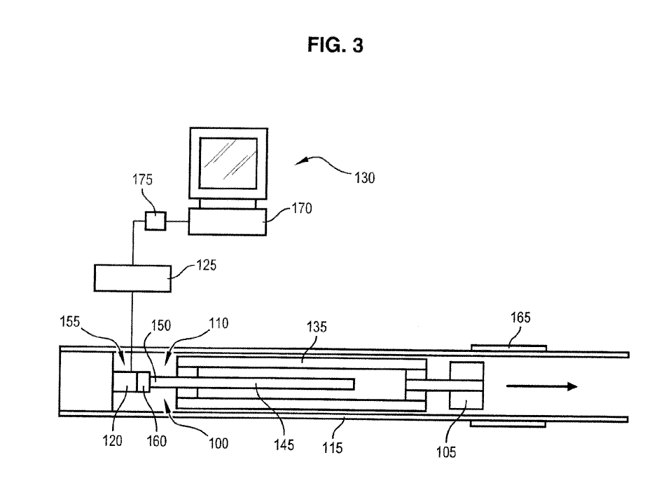

FIG. 3 is a schematic representation, in longitudinal section, of the detection device according to the invention introduced into a tube comprising a fouling deposit,

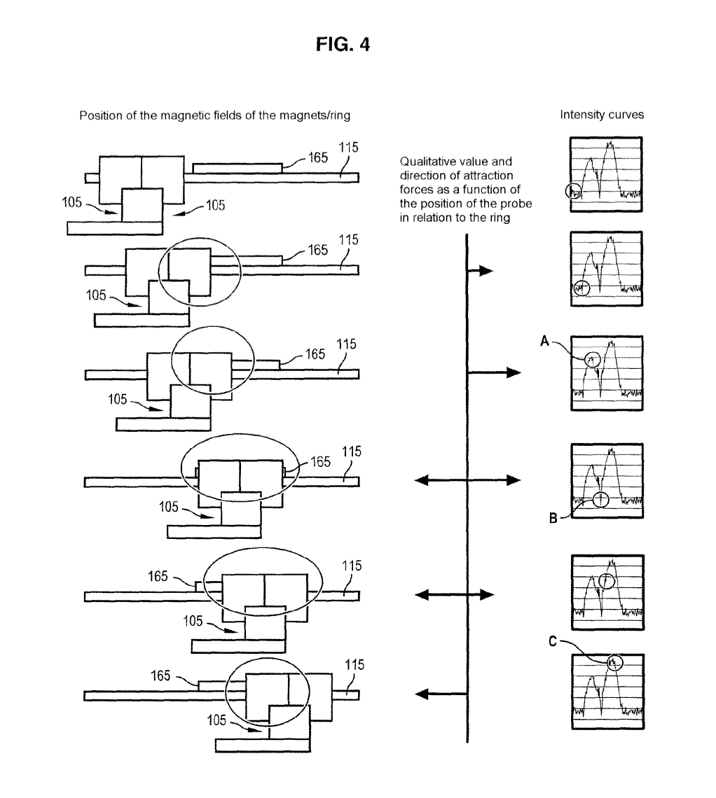

FIG. 4 is a schematic representation of the different positions of the probe of the device according to the invention relative to deposit, attraction forces as a function of the position of the probe and variations in intensity of the current motor,

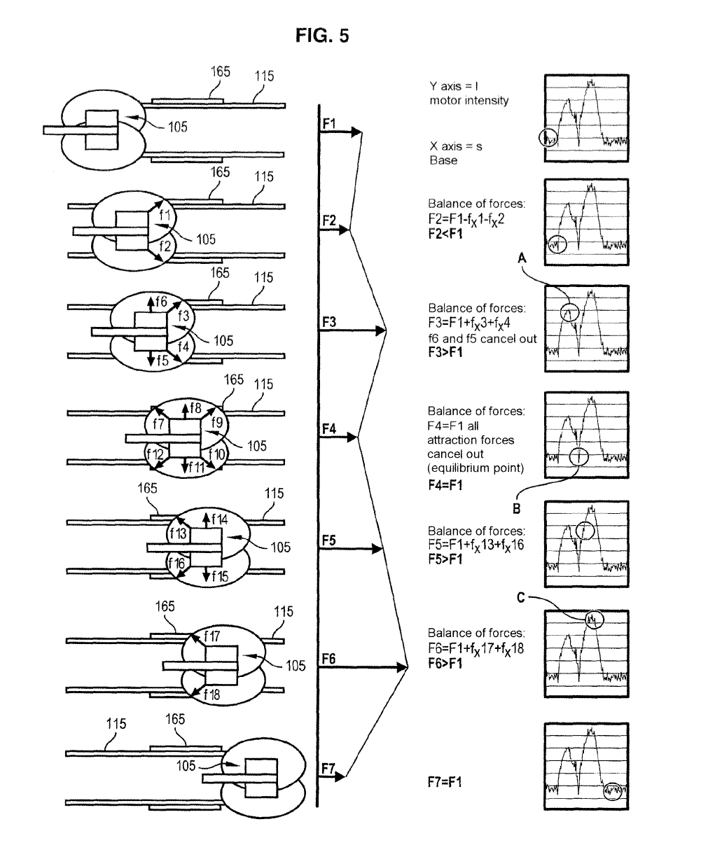

FIG. 5 is a schematic representation of the different positions of the probe of the device according to the invention relative to deposit, attraction forces as a function of the position of the probe, the balance of forces, and variations in intensity of the current motor,

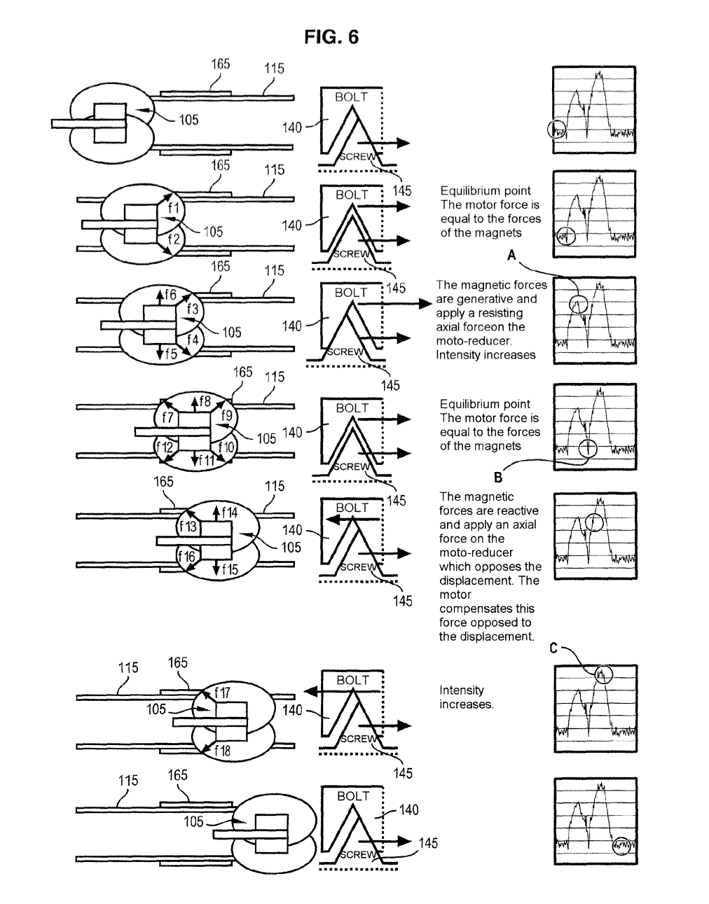

FIG. 6 is a schematic representation of the different positions of the probe of the device according to the invention relative to deposit, attraction forces as a function of the position of the probe, forces exerted on the threads of the screw and the bolt of the moving means of the probe, and variations in intensity of the current motor,

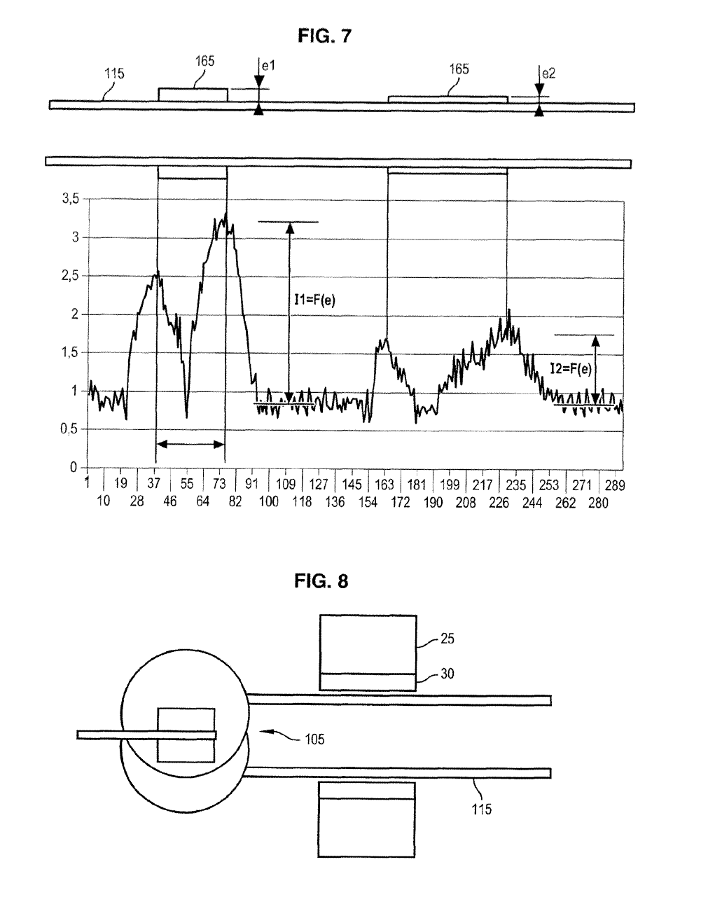

FIG. 7 is a graphic representation of the variations in intensity of the current motor when the probe of the device according to the invention is moved in a tube comprising fouling deposits of different thickness and length,

FIG. 8 is a view in longitudinal section of the probe of the device according to the invention introduced into a tube at the level of a quadrifoliage of a spacer plate,

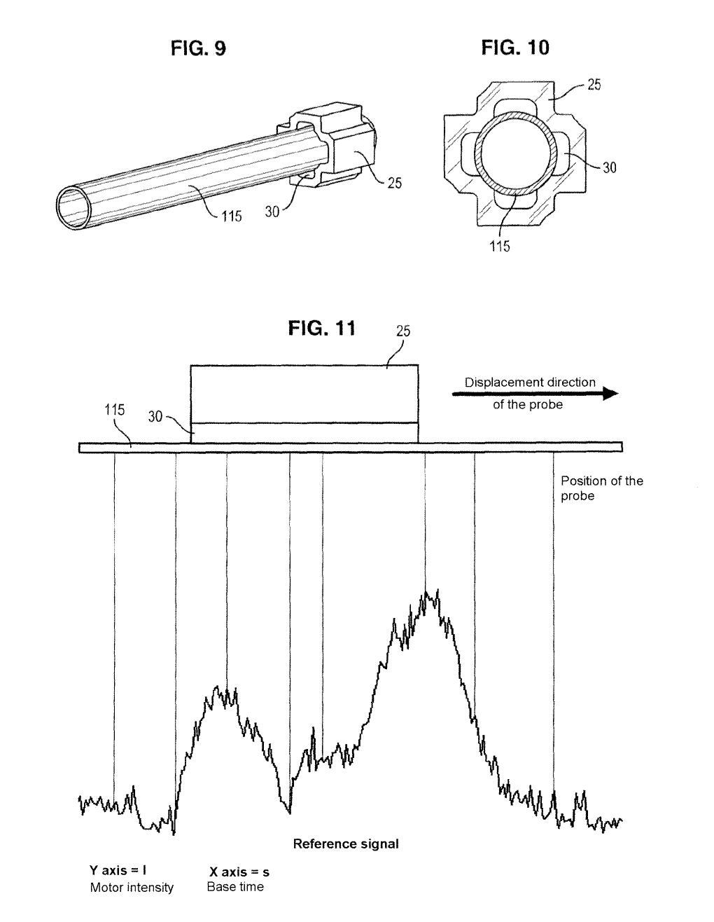

FIG. 9 is a view in partial perspective of a tube passing into the quadrifoliage of a spacer plate,

FIG. 10 is a view in section along the section line X-X′ of a tube and a quadrifoliage illustrated in FIG. 9,

FIG. 11 is a graphic representation of the variations in intensity of the current motor when the probe of the device is moved in a tube, in a first direction, at the level of a quadrifoliage not comprising clogging deposit,

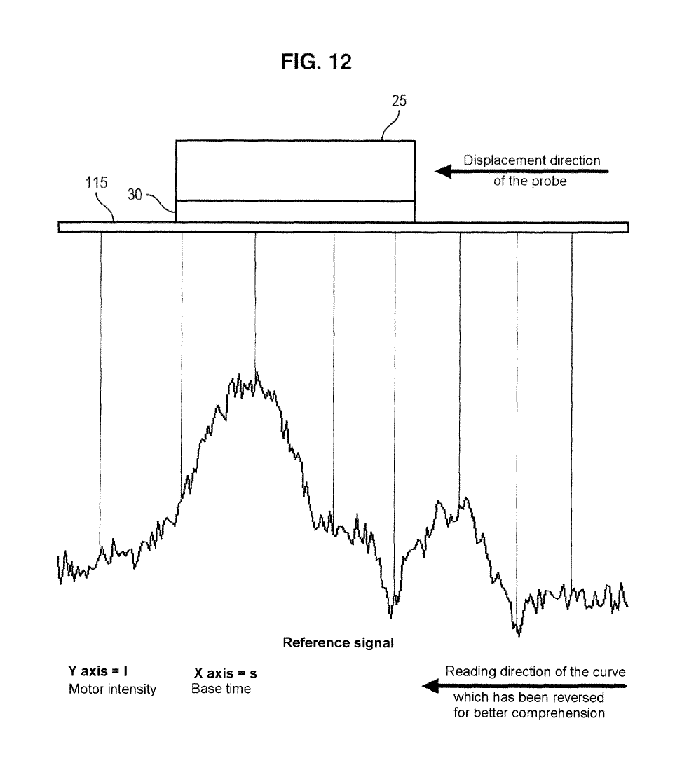

FIG. 12 is a graphic representation of the variations in intensity of the current motor when the probe of the device is moved in a tube, in an opposite direction, at the level of a quadrifoliage not comprising a clogging deposit,

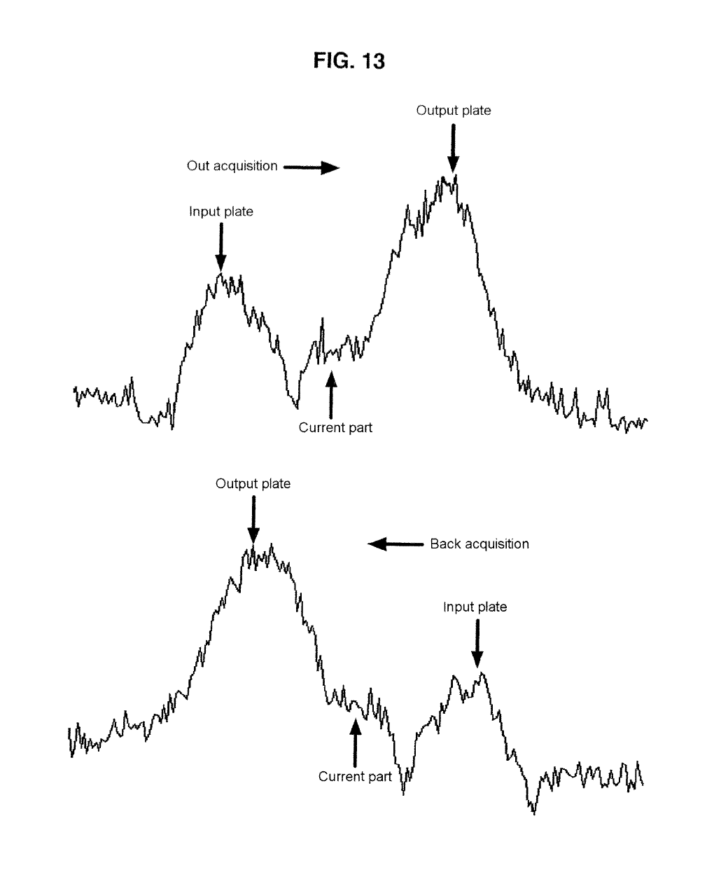

FIG. 13 is a graphic representation of the variations in intensity of the current motor when the probe of the device is moved in a tube, in a first direction and then in the opposite direction, at the level of a quadrifoliage not comprising clogging deposit,

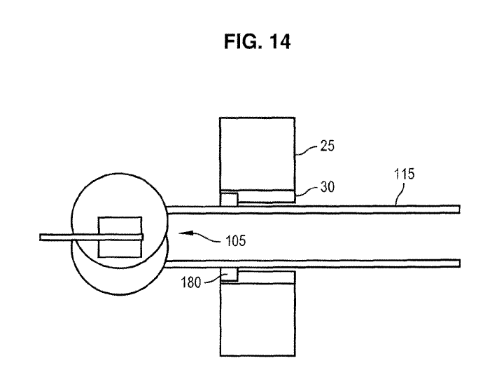

FIG. 14 is a view in longitudinal section of the probe of the device according to the invention introduced into a tube at the level of a quadrifoliage of a spacer plate comprising a clogging deposit,

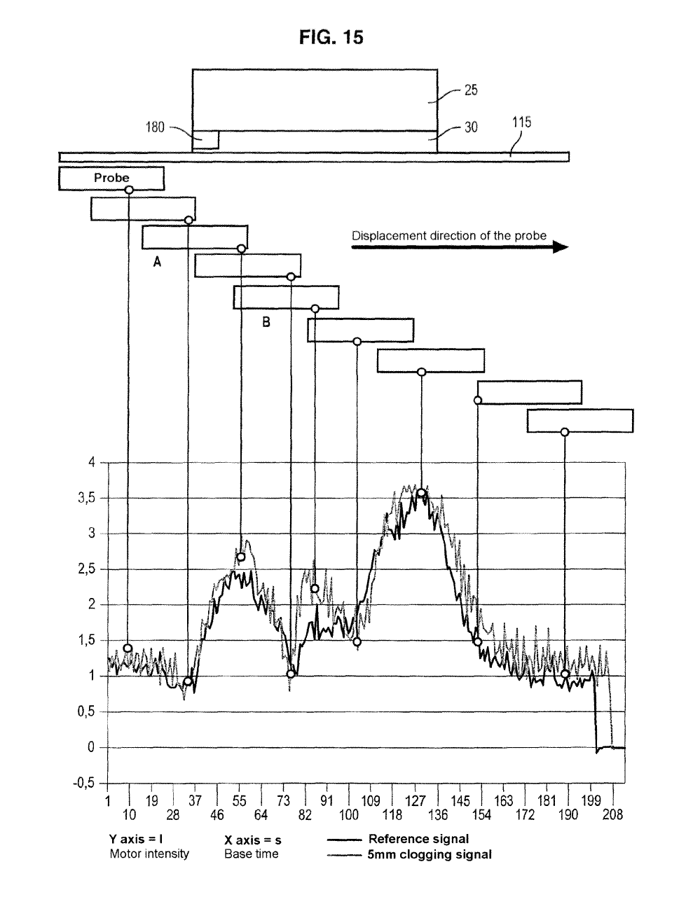

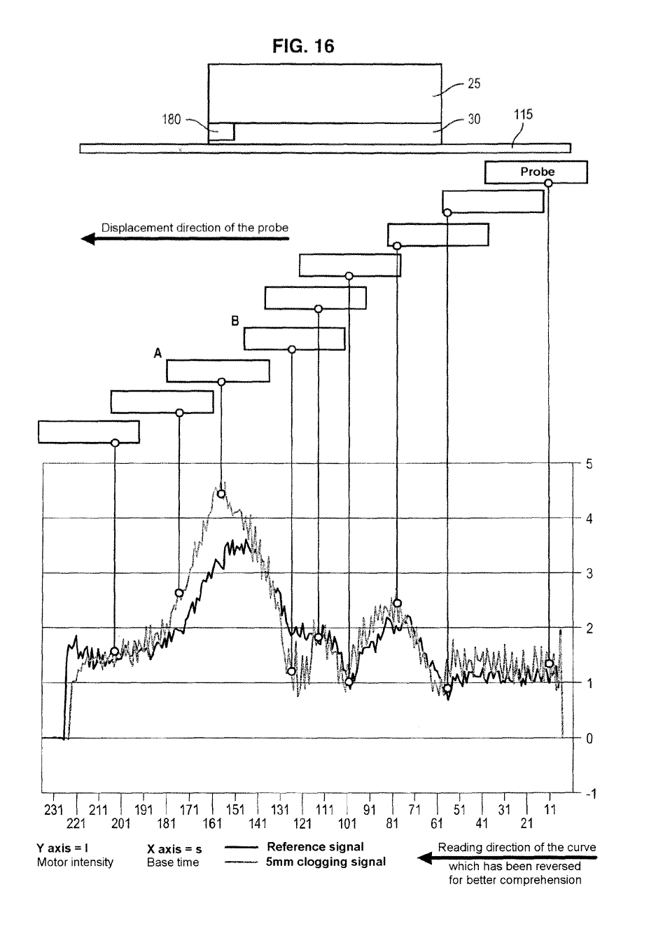

FIG. 15 is a graphic representation of the variation in intensity of the current motor of the device according to the invention when the probe is moved, in a first direction, in a tube at the level of a quadrifoliage comprising a clogging deposit,

FIG. 16 is a graphic representation of the variation in intensity of the current motor of the device according to the invention when the probe is moved, in an opposite direction, in a tube at the level of a quadrifoliage comprising a clogging deposit,

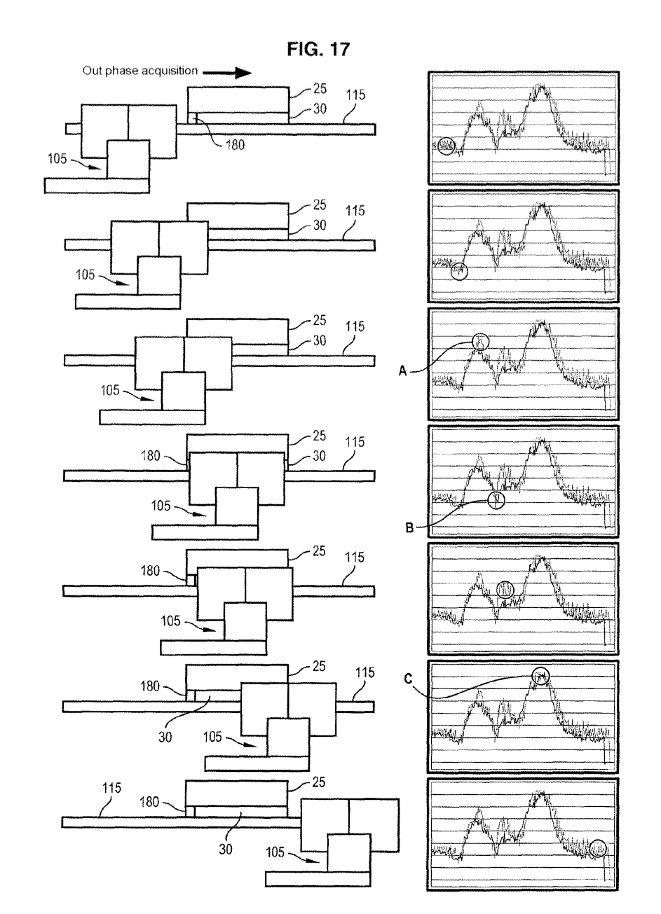

FIG. 17 is a schematic representation of the different positions of the probe of the device according to the invention relative to a deposit, attraction forces as a function of the position of the probe, and variations in intensity of the current motor when the probe is moved, in a first direction, in a tube at the level of a quadrifoliage comprising a clogging deposit,

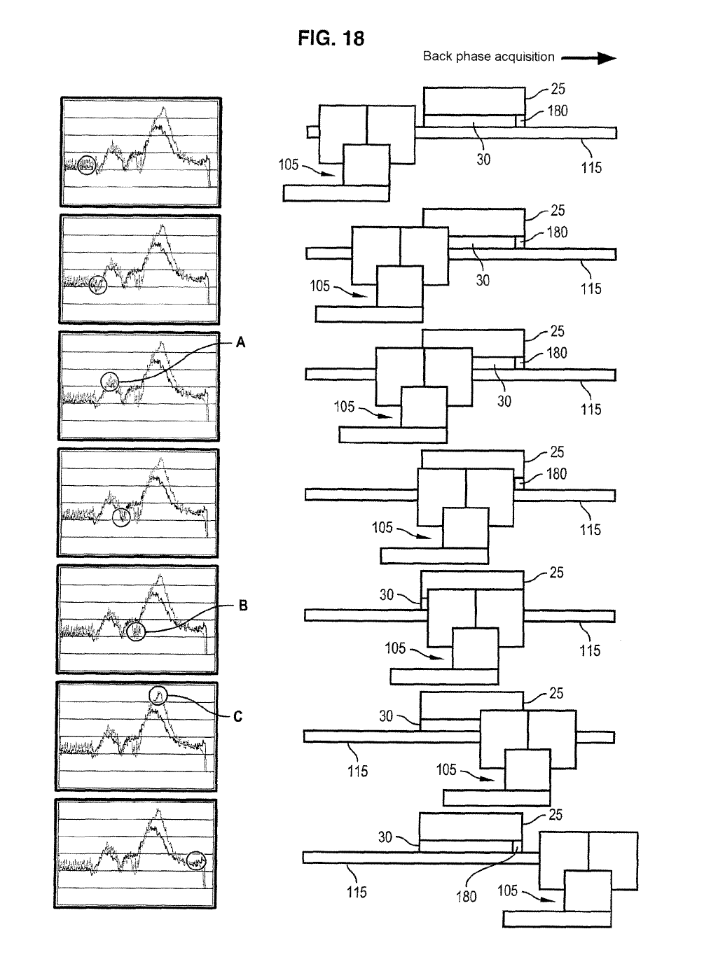

FIG. 18 is a schematic representation of the different positions of the probe of the device according to the invention relative to deposit, attraction forces as a function of the position of the probe, and variations in intensity of the current motor when the probe is moved, in an opposite direction, in a tube at the level of a quadrifoliage comprising a clogging deposit.

### DETAILED DESCRIPTION OF THE INVENTION

In reference to FIG. 1, the detection device 100 according to the invention comprises a magnetised source 105 comprising one or more permanent magnets, said magnetised source 105 forming a probe, moving means 110 of said magnetised source 105 inside a tube 115 in the direction of its length, said moving means 110 comprising at least one electric motor 120, as will be detailed hereinbelow, means for measuring the intensity of the current 125 in said electric motor 120 and means 130 for determining the position and/or thickness and/or volume of a deposit on or near the external wall of the tube 115, as a function of variations in intensity of the current measured in the electric motor 120.

The moving means 110 of the magnetised source 105 consist of a piston 135 whereof one of the ends bears said magnetised source 105 and whereof the opposite end comprises a bolt 140 cooperating with an endless screw 145 solid with a rotary drive axle 150. Said rotary drive axle 150 consists of the output axle of a moto-reducer 155 constituted by a reducer 160 coupled to an electric motor 120. Said electric motor 120 is powered by fixed voltage regulated such that, to compensate for the increase in power necessary to pass the hard points associated with attraction of the magnets of the magnetised source 105, the intensity of the current motor increases.

In fact, having a magnetised source 105 called a probe, constituted by one or more permanent magnets, near a deposit 165 comprising at least one ferromagnetic material, such as nickel, magnetite or similar, on or near the external wall of the tube 115, results in attraction forces which vary as a function of the volume of the deposit 165, the distance between the probe 105 and the deposit 165, and the relative position between the probe 105 and the deposit 165. Moving this probe 105 is motorised at a constant speed, under the effect of attraction forces, results in variation in intensity of the supply current of the motor 120 which calibrates, detects the presence and estimates the volume of the deposit 165. Maximal force is attained when the minimum volume of the magnetic material is equal to the volume of the magnet of the probe 105. The attraction forces generated by the permanent magnets of the probe can be active or resistant, can favour displacement or oppose displacement. The control process by magnetic probe of the fouling and clogging consists of motorising in the tube 115 displacement of a probe 105 at a constant speed, comprising one or more permanent magnets, and making acquisition of the current motor whereof the intensity varies as a function of the presence, distance and volume of deposits.

Also, acquired signals are compared to the signal tube or to calibrated reference signals representative of dimensional data of deposit forms.

Also, to keep the device in place inside the tube 115 during displacement of the probe, the device comprises blocking means 165 of the moving means 110 inside said tube 115. Said blocking means 115 will be able to consist of all means well known to the person skilled in the art, such as mechanical means or plastic deformation means for example.

Also, the means for measuring the intensity of the current 125 consist of a device of ammeter type connected to a computer 170 of PC type by means of an acquisition card USB 175. An algorithm in the form of registered software on a physical medium, such as a hard drive and/or computer memory 165, the position and/or the thickness and/or volume of a deposit on or near the external wall of the tube 115, as a function of variations in intensity of the current measured in the electric motor 120, measurements of the intensity being transmitted to the computer 170 by means of the acquisition card USB 175.

An explanation now follows of the function of the device for detecting deposits comprising at least one ferromagnetic material, such as nickel, magnetite or similar, on or near the external wall of an amagnetic tube, in reference to FIGS. 3 to 18.

The device according to the invention, in reference to FIG. 3, is blocked in a tube 115 comprising a fouling deposit 165 simulated by a magnetic ring.

When the probe 105 is moved at constant speed in the amagnetic tube 115, it is necessary to exert motorisation force of the probe depending on its position relative to the deposit 165.

The probe 105 is moved at constant speed, the voltage being regulated, the power function of the electric motor 120 with continuous current written as P(t)=U×l(t).

The intensity l(t) varies as a function of the relative position between the permanent magnets of the probe 105 and the deposit 165, said relative position generating a variation in attraction forces.

In some phases (input and output of the zone of the deposit 165), the attraction forces tend to draw on mechanics and generate axial restrictions which are compensated by the current motor.

The marker points on the curves of FIG. 4 give information on the start of ring (A) and finish of ring (C). The length of the deposit 165 is equal in this case to X(C)-X(A), where X is equal to the base time multiplied by the speed of displacement of the probe 105.

A highly characteristic point of these curves is the point of inflection (B) which indicates that the probe is in material equilibrium, that is, that there is as much magnetic material on either side of the normal axis of the probe 105.

FIG. 5 discloses the behaviour of the probe 105 when it is subjected to attraction forces and graphic elements are taken therefrom to structure analysis. For each relative position of the probe 105 relative to the deposit 165, this FIG. 5 shows the diagram of the attraction forces, the balance of forces in play, that is, the balance of the motor force and the attraction forces, the impact on mechanical transmission and their link to the motor intensity curve.

It is evident that the value of these forces depends on the volume of deposits encountered.

To retain displacement at constant speed the motor 120 must compensate for the effect of attraction forces when they are powered or resistant.

When they are powered, they are more substantial than the advance force. In reference to FIG. 6, their effect is to draw on the screw/bolt transmission and consequently generate stress on the threads.

In the case of the particular embodiment of the invention in which transmission consists of a transmission via screw/bolt, magnetic forces generate an axial force on the axle of the moto-reducer. These magnetic forces are sometimes so powered that they become resistant for mechanics.

In reference to FIG. 7, which illustrates the variation in intensity of the current motor when the probe of the device is moved inside a tube 115 comprising two rings of different thickness and length, said rings simulating deposits of different thickness and length, it appears that analysis of the form of the acquired signal produces data relative to the start of the deposit, to the length of the deposit, correlated with the speed of advance, and to the thickness of the deposit (e1 or e2), correlated with the amplitude of the intensity of standard rings.

Consequently, the device according to the invention detects the presence of a deposit around the tube and determines the length of these deposits and their thickness.

Also, the device according to the invention enables direct on-screen reading of results by comparing the acquired signals to the reference tube signal or to calibrated signals.

In reference to FIGS. 8 to 10, the process according to the invention can be applied to the plate tube/spacer link. Analysis of moving forces (function of the position of the probe relative to the spacer plate) helps determine whether there is a variation in volume of material.

Tests conducted using the device according to the invention have shown that the variation in volume of deposits could be detected by comparison to a reference signal, the reference signal consisting of variations in intensity of the current motor when the probe is moved in a tube comprising no deposit, or by the difference in plate input and output signals. If there is a clogging deposit, it is present on one side of the spacer plate only, which compares the corresponding signals.

In the case of comparative input/output analysis, to boost precision for detection and characterisation of deposits, it is necessary to make a double acquisition (out and back) since the behaviour of the probe is different if entry is made via the clogged side or exit is made via the clogged side.

The first assay, in reference to FIGS. 11 and 12, consists of the device according to the invention acquiring the intensity of reciprocal displacement of the probe in a tube mounted in a spacer plate whereof the quadrifoliage passages are not obstructed.

In reference to FIG. 13, this shows the relation between the position of the probe relative to the spacer plate and the motor acquisition curve.

To analyse the signals, characteristic points must be located on the curve. A variation in intensity of the current motor at these points will reveal the presence of a variation in volume of material, that is, the presence of a clogging deposit.

In reference to FIG. 14, a clogging deposit 180 was simulated by positioning a magnetic ring in the quadrifoliage passage of a spacer plate.

In reference to FIGS. 15 and 17, an evolution in signals for the two reference points (A) and (B) is evident. At the plate inlet (A), there is more material as the attraction forces are higher, and they draw on the transmission generating a resistant force which the motor compensates by the increase in current.

In the current part (B), the attraction forces due to deposit at the plate intake hold the probe, leading to an increase in intensity.

In reference to FIGS. 16 and 18, an evolution in signals for the two reference points A and B is evident. At the plate outlet (A), there is more material as the attraction forces are higher, and they push on the transmission generating a resistant force which the motor compensates by the increase in current. In the current part (B), the attraction forces due to deposit at the plate outlet attract the probe and keep it in equilibrium for some time, resulting in a decrease in intensity.

Consequently, the device according to the invention detects clogging of the quadrifoliage passages of the spacer plates with fine sensitivity, and determines the depth of this clogging and its thickness.

Also, the device according to the invention enables direct on-screen reading of results by comparing signals acquired at the reference tube signal or at calibrated signals.

Finally, it is understood that the examples given hereinabove are only non-limiting particular illustrations as to fields of application of the invention.

1. A process for detecting fouling deposits or clogging comprising at least one ferromagnetic material, such as nickel, magnetite or similar, on or near the external wall of a tube, characterised in that it comprises at least the following steps of:
moving a magnetised source inside the tube in the direction of its length by means of an electric motor,
measuring the intensity of the current in the electric motor, and
determining the position and/or thickness and/or volume of said deposit as a function of the variations in intensity of the current measured in the electric motor.

2. The process as claimed in the preceding claim, characterised in that the magnetised source consists of at least one permanent magnet.

3. The process as claimed in any one of claim 1 or 2, characterised in that said magnetised source is moved in the tube at a constant speed.

4. The process as claimed in any one of claims 1 to 3, characterised in that the magnetised source is moved in a first direction and then in its opposite direction.

5. The process as claimed in any one of claims 1 to 4, characterised in that the step of determining the position and/or thickness and/or volume of said deposit comprises a comparison step of the variation in intensity of the current measured in the motor with a reference model and/or a calibrated model.

6. A device for detecting fouling deposits or clogging comprising at least one ferromagnetic material, such as nickel, magnetite or similar, on or near the external wall of a tube, characterised in that it comprises at least one magnetised source, moving means of said magnetised source inside of said tube in the direction of the length comprising an electric motor, means for measuring the intensity of the current in said electric motor and means for determining the position and/or thickness and/or volume of said deposit as a function of the variations in intensity of the current measured in the electric motor.

7. The device as claimed in claim 6, characterised in that the magnetised source consists of at least one permanent magnet.

8. The device as claimed in any one of claim 6 or 7, characterised in that the moving means of the magnetised source consist of a piston whereof one of the ends bears said magnetised source and whereof the opposite end comprises a bolt cooperating with an endless screw solid with the rotary drive axle.

9. The device as claimed in claim 8, characterised in that the rotary drive axle consists of the output axle of a reducer coupled to an electric motor.

10. The device as claimed in any one of claims 6 to 9, characterised in that it comprises blocking means of the drive means inside a tube.

11. Application of the process as claimed in any one of claims 1 to 5 for detection of deposits in the quadrifoliages of the spacers of a steam generator of a pressurised nuclear water reactor known as PWR.
